(19) United States
(12) Patent Application Publication
(10) Pub. No.: US 2012/0138230 A1
(43) Pub. Date: Jun. 7, 2012

(54) SYSTEMS AND METHODS FOR MOVING WEB ETCH, CVD, AND ION IMPLANT

(76) Inventors: Terry BLUCK, Santa Clara, CA (US); Young Kyu Cho, San Jose, CA (US); Dennis Grimard, Ann Arbor, MI (US); Karthik Janakiraman, San Jose, CA (US); Moon Chun, San Jose, CA (US)

(21) Appl. No.: 13/312,957

(22) Filed: Dec. 6, 2011

Related U.S. Application Data
(60) Provisional application No. 61/420,143, filed on Dec. 6, 2010.

(51) Int. Cl. B65G 15/48; C23F 1/08; G21K 5/10; C23C 16/458

(52) U.S. Cl. 156/345.54; 118/729; 250/492.21

(57) ABSTRACT

Systems and methods for moving substrates through process chambers for photovoltaic (PV) or solar cell applications are disclosed. In particular, systems and methods for moving substrates through process chambers using a conveyor belt are disclosed. The conveyor belt can be used to move the substrates through etch chambers, chemical vapor deposition (CVD) chambers, and/or ion implant chambers, and the like.

### PRIORITY

The present application claims priority to U.S. Provisional Application No. 61/420,143, filed Dec. 6, 2010, and entitled “MOVING WEB ETCH, CVD AND ION IMPLANT,” the entirety of which is hereby incorporated by reference.

### BACKGROUND

1. Field

This invention relates to the art of methods for making silicon wafers for solar cells and, more particularly, to moving web etch, CVD and ion implant of solar wafers.

2. Related Art

Solar cells, also known as photovoltaic (PV) cells, convert solar radiation into electrical energy. Solar cells are fabricated using semiconductor processing techniques, which typically, include, for example, deposition, doping and etching of various materials and layers. Typical solar cells are made on semiconductor wafers or substrates, which are doped to form p-n junctions in the wafers or substrates. Solar radiation (e.g., photons) directed at the surface of the substrate cause electron-hole pairs in the substrate to be broken, resulting in migration of electrons from the n-doped region to the p-doped region (i.e., an electrical current is generated). This creates a voltage differential between two opposing surfaces of the substrate. Metal contacts, coupled to electrical circuitry, collect the electrical energy generated in the substrate.

Silicon photovoltaic (PV) cells are manufactured using processes that are similar to conventional semiconductor processing techniques. However, the difference in value of a PV cell compared to a wafer is orders of magnitude. The PV industry needs high throughput at low capital and running cost. Also, the substrate for PV cells is typically very thin (e.g., <200 um thick) and fragile.

SiO₂ and SiN are frequently deposited using high temperature chemical vapor deposition (CVD). The wafers are transferred individually onto pins that extend up from a heater inside a CVD process chamber by vacuum robots. The process times are relatively short (e.g., <10 seconds for films that are about 1000 Angstroms). More time is spent in substrate handling than in the actual process time. In addition, the lift pins and repeated robot handoffs greatly increase the likelihood of wafer damage.

During deposition, process kits inside the chamber build up with deposition. This build-up starts to cause particles to be introduced into the process as the build-up thickens and flakes off the chamber walls. The chamber is in situ cleaned periodically to extend the lifetime of the process kit and reduce the chamber vent frequencies for service. The chamber is typically cleaned by fluorine radicals. These fluorine radicals are typically created by a remote plasma source and are introduced into the chamber. Fluorine is an aggressive oxidizing agent and therefore the materials used inside the process chamber must be selected to withstand the clean process and high temperatures.

Semiconductor electrostatic chucks are used in some semiconductor process chambers (e.g., etching and ion implant). These semiconductor electrostatic chucks are extremely expensive. In addition, complicated methods are required to transfer the substrate to and from the chuck. These methods for transferring the wafer are too expensive, have too little throughput and often damage the very thin, fragile PV cells.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

According to an aspect of the invention, a chemical vapor deposition (CVD) system is provided that includes a CVD chamber comprising an inlet and an outlet; and a conveyor belt to transport wafers from the inlet of the chamber to the outlet of the chamber.

The conveyor belt may be an aluminum oxide fabric belt. The conveyor belt may include a roller at each end of the conveyor belt.

The system may further include a grounded electrode, wherein the conveyor belt passes over the grounded electrode. The system may further include a grounded drag plate to support the conveyor belt and the grounded electrode.

The conveyor belt may operate in a continuous mode. The conveyor belt may operate in a static mode. The conveyor belt may operates in a start/stop with left/right and forward backward/jog mode.

The chamber may further include a vacuum system and a radio frequency (RF) powered shower head.

According to another aspect of the invention, an etching system is provided that includes an etch chamber comprising an inlet and an outlet; and a conveyor belt to transport wafers from the inlet of the chamber to the outlet of the chamber.

The conveyor belt may be an aluminum oxide fabric belt. The conveyor belt may include a roller at each end of the conveyor belt.

The system may further include a direct current (DC) electrode coupled to the conveyor belt. The system may further include a cooled radio frequency (RF) biased drag plate coupled to the DC electrode, the drag plate to support the conveyor belt and provide bias power to the wafer, chuck the wafer and cool the wafer.

The etch chamber may further include a vacuum system and at least one radio frequency powered coil to generate the plasma for the chamber.

The conveyor belt may operate in a continuous mode. The conveyor belt may operate in a static mode. The conveyor belt may operates in a start/stop with left/right and forward backward/jog mode.

According to a further aspect of the invention, an ion implant system is provided that includes an ion implant chamber comprising an inlet and an outlet; and a conveyor belt to transport wafers from the inlet of the chamber to the outlet of the chamber.

The conveyor belt may be an aluminum oxide fabric belt. The conveyor belt may include a roller at each end of the conveyor belt.

The conveyor belt may operate in a continuous mode. The conveyor belt may operate in a static mode. The conveyor belt may operates in a start/stop with left/right and forward backward/jog mode.

The chamber may further include a vacuum system and at least one ion implant source.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is a perspective view of a conveyor belt according to one embodiment of the invention.

FIG. 2 is a perspective view of a conveyor belt with multiple substrates according to one embodiment of the invention.

FIG. 3 is a perspective view of a conveyor belt for a chemical vapor deposition (CVD) chamber according to one embodiment of the invention.

FIG. 4 is schematic diagram of a CVD chamber with the conveyor belt according to one embodiment of the invention.

FIG. 5 is a schematic diagram of an etch chamber with the conveyor belt according to one embodiment of the invention.

FIG. 6 is a schematic diagram of an ion implant chamber with the conveyor belt according to one embodiment of the invention.

### DETAILED DESCRIPTION

Embodiments of the invention are directed to systems and methods for moving substrates through process chambers for photovoltaic (PV) or solar cell applications. In particular, embodiments of the invention are directed to systems and methods for transporting substrates through process chambers using a conveyor belt. The conveyor belt can be used to move the substrates through etch chambers, chemical vapor deposition (CVD) chambers, and/or ion implant chambers, and the like.

Embodiments of the invention are advantageous because expensive robots are not needed to move the substrates during processing. In addition, lift pins are not needed to process the substrates, which reduces the risk of damage to the substrates during processing.

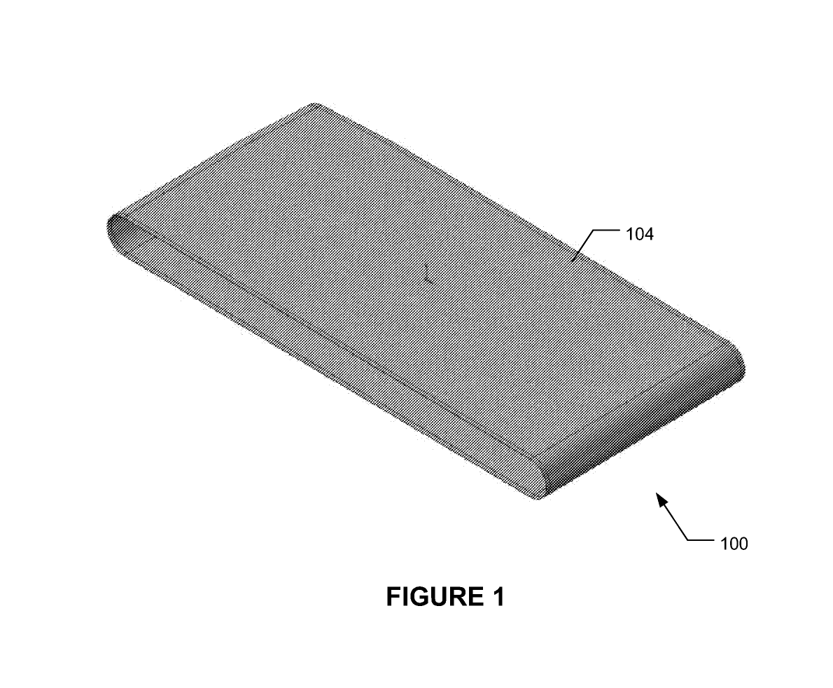

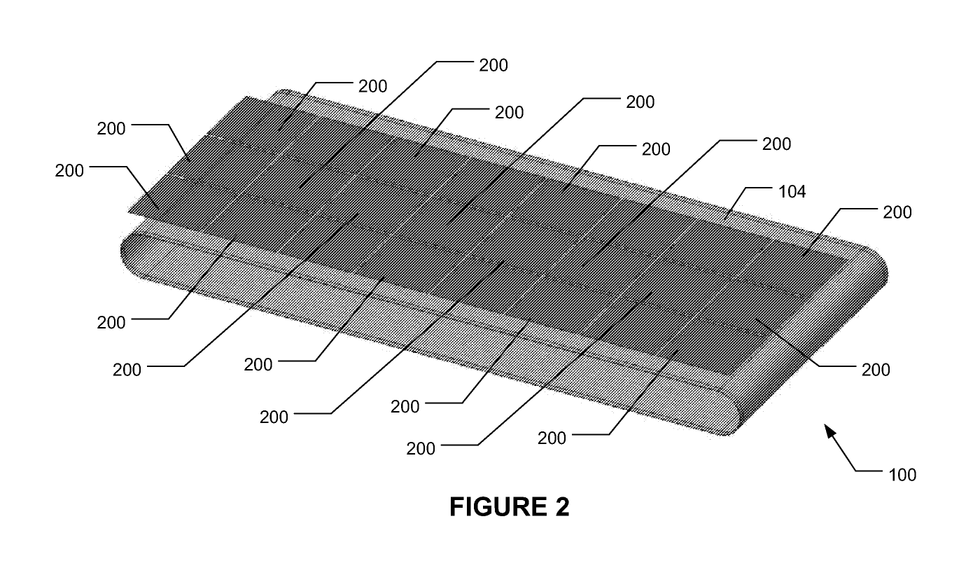

FIGS. 1 and 2 illustrate a transport system 100 in accordance with one embodiment of the invention. The transport system 100 is configured to transport wafers for PV applications through one or more process chambers. The transport chamber 100 includes a conveyor belt 104. In some embodiments, one or more of the process chambers used to make the PV cell includes a separate conveyor belt 104. For example, a deposition chamber (e.g., a CVD chamber), an etch chamber and an ion implant chamber may each include separate conveyor belts 104. In some embodiments, the conveyor belts 104 of the process chambers may be in communication with one another so that substrates can be transferred directly from one conveyor belt to another conveyor belt for processing in each of the process chambers. In some embodiments, one conveyor belt 104 can be used for processing in each of the process chambers (i.e., the same conveyor belt 104 allows for processing in each of, for example, the CVD chamber, the etch chamber and the ion implant chamber).

The conveyor belt 104 is made of a material that can withstand at least the high temperature required during the deposition process and the fluorine chemistry used during the cleaning process. In some embodiments, the conveyor belt 104 is made from an aluminum oxide fabric.

As shown in FIG. 2, the conveyor belt 100 is configured to hold one or more substrates 200. The conveyor belt 100 moves the substrates 200 through the process chambers (e.g., entering one side of the process chamber and exiting the other side of the process chamber). The conveyor belt 100 can move the substrates 200 through the chamber in a pass-by mode, a static mode or a start/stop mode. In the pass-by mode, the conveyor belt 100 continuously moves the substrates through the process chamber(s). In the static mode, the conveyor belt 100 moves in discrete steps and remains stationary during the process. In the start/stop mode, the conveyor belt 100 can move the substrate left/right and forward/backward in the process chamber(s).

### Chemical Vapor Deposition

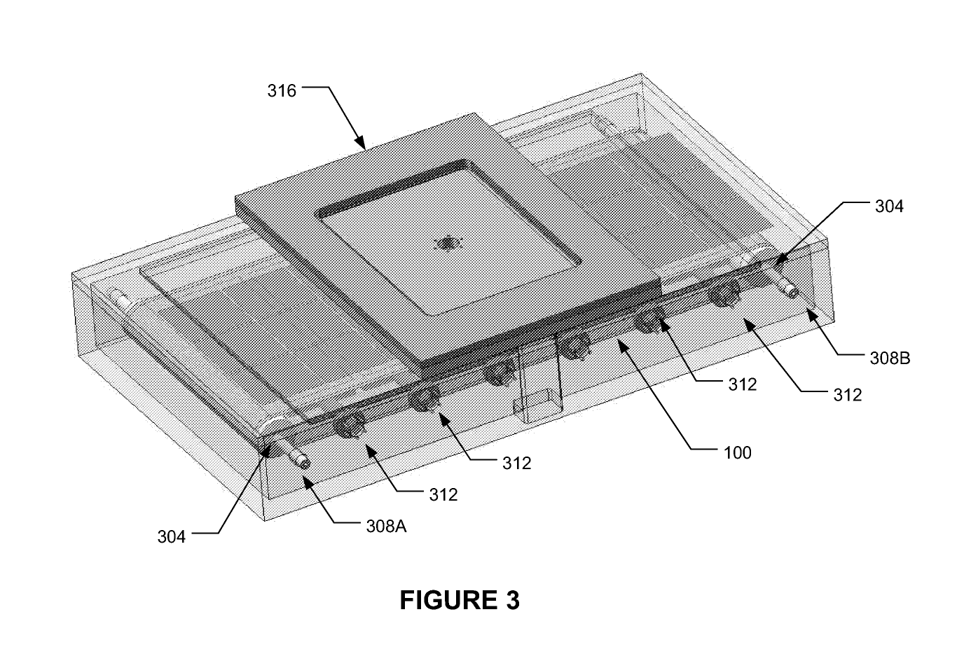

As shown in FIG. 3, the conveyor belt 100 is driven by rollers 304 on both ends 308a, 308b of the conveyor belt 100. The conveyor belt 100 rides on top of one or more grounded electrodes 312 in the form of a grounded drag plate(s). The grounded electrode 312 is used to enhance film performance. The grounded electrode may be a heater or the grounded electrode may be heated by a heater to the process temperature. For example, the grounded electrode may be used to heat the conveyor belt 100 to between about 400 and about 550° C. It will be appreciated that the conveyor belt may be heated to less than about 400° C. and/or more than about 550° C. In FIG. 3, six grounded electrodes 312 are shown. It will be appreciated however that the number of grounded electrodes 312 may be less than or more than six. An RF electrode 316 is shown positioned over the belt 100 and substrates 200. In one embodiment, the RF electrode 316 can cover multiple rows of substrates 200.

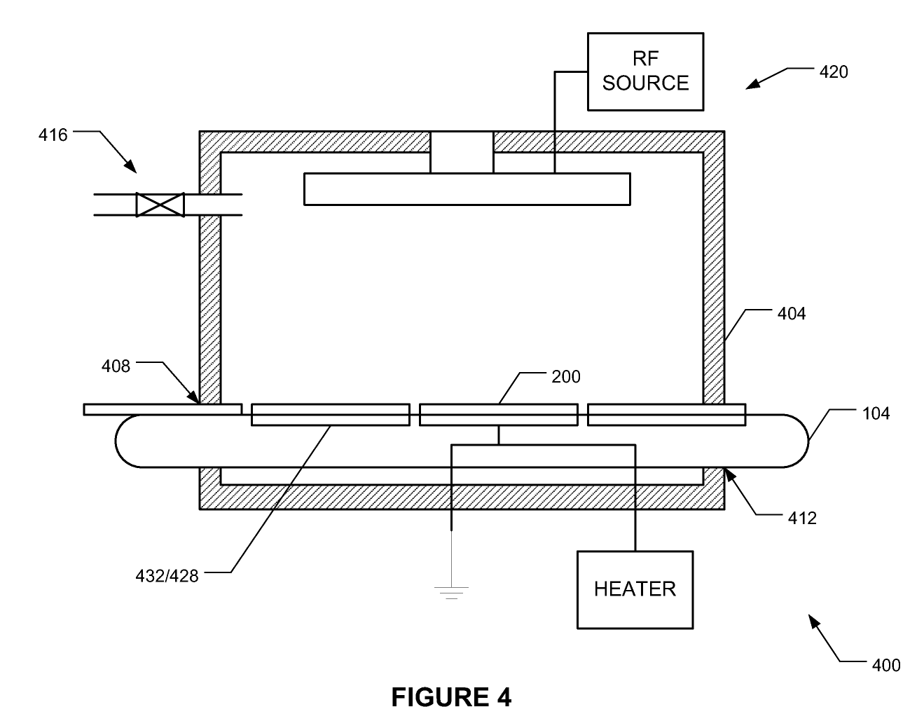

FIG. 4 illustrates an exemplary CVD process system 400 that includes the conveyor belt 104. As shown in FIG. 4, the CVD process chamber 400 is a vacuum chamber 404 with a substrate inlet 408, substrate outlet 412, a vacuum system 416, and an RF powered shower head 420. The RF powered shower head 420 is used to introduce gas and generate the plasma. As shown in FIG. 4, the chamber 400 also includes the conveyor belt 104 to transport the substrates 200, a heater(s) 424 for heating the belt and substrate, a grounded drag plate 428 for supporting the belt 104 and providing a grounded electrode 432 beneath the substrate 200. In some embodiments, the grounded drag plate 428 is stationary and the belt 104 drags over the top of the grounded drag plate 428.

To reduce the buildup of CVD deposited material on the belt 104 between substrates 200, the belt 104 may be jogged perpendicular to the direction of travel as each row of substrates 200 is transferred from the incoming chamber. The substrates 200 are transferred to the moving belt from another belt or robotic device. It will be appreciated that it may be advantageous to do belt to belt transfers of substrates to avoid potential issues between the relative speed of the substrate and the belts. This places the substrates 200 onto different areas of the belt 104 without changing the substrates 200 path onto or off of the belt 104 at the inlet and outlet of the chamber 404.

### Etch

The conveyor belt 104 can also be used with an etch chamber. The surface of a PV cell substrate is typically dry etched. In particular, CₓF_{y} or SF₆ gas and an RF plasma are used for texture or back contact etching the substrate. As in semiconductor etching, in PV cell etching, an RF bias is applied to the substrate and electrostatic chuck. For etching, therefore, the conveyor belt needs to be able to work in a fluorine radical rich environment, electrostaticly chuck the substrate and provide an RF bias to the substrate. An aluminum oxide fabric conveyor belt can be used in the etch chamber. The belt is driven by rollers on both ends of the belt, and rides on top of a RF biased electrode, which is cooled or kept at room temperature. The electrode is also connected to a high voltage DC power supply to electrostaticly chuck the substrate. In some embodiments, the etch belt is made of the same material as the CVD belt; however, the belts may be made of different materials. It will be appreciated that belt material may be select based on belt that is best for the particular process.

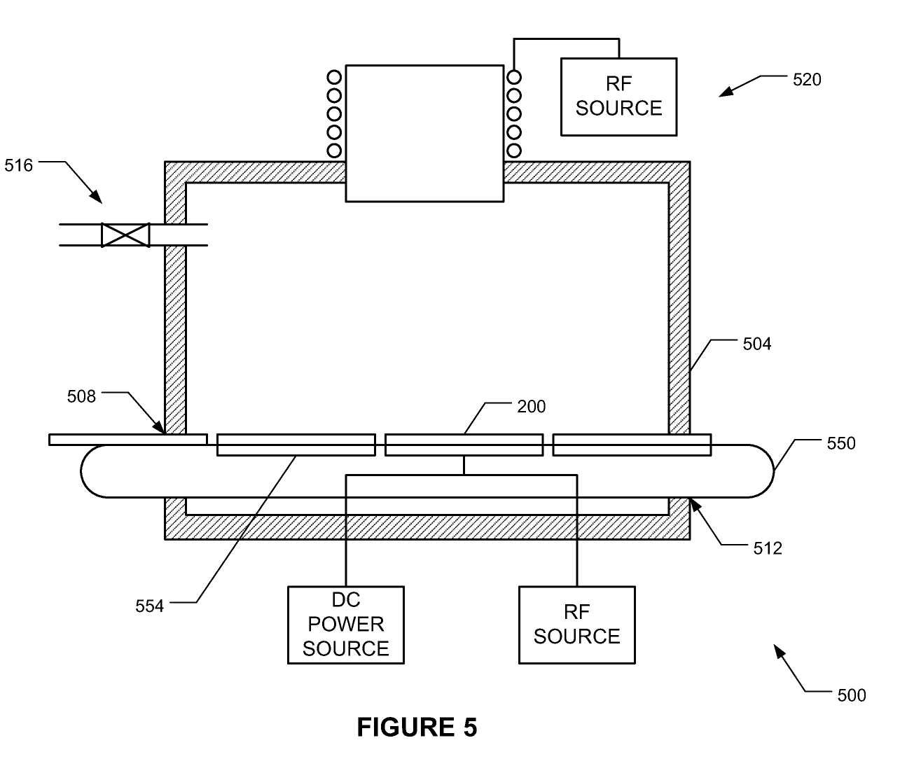

FIG. 5 illustrates an exemplary etch system 500 that includes a conveyor belt according to embodiments of the invention. The etch chamber 500 includes a vacuum chamber 504 with a substrate inlet 508, substrate outlet 512, a vacuum system 516, and RF powered coil(s) 520. The RF powered coils generate the plasma for the chamber 504. The etch chamber 500 also includes an aluminum oxide conveyor belt 550 to transport the substrates 200 between the inlet 508 and outlet 512. The etch chamber 500 also includes a cooled RF biased, DC powered drag plate 554 to support the belt and provide bias power, chuck and cool the substrate 200. The belt 550 is advantageous because it avoids the need for expensive robots, complicated lift pins and reduces possible damage to the substrates.

The conveyor belt 550 moves the substrates 200 through the process chamber 504, coming in one side 508 and exiting the other side 512. The process can be run in either a pass-by mode, a static mode or a start/stop mode. In the pass-by mode, the belt 550 continuously moves the substrates 200 through the process zone. In the static mode, the belt 550 moves in discrete steps and remains stationary during the process. In the start/stop mode, the conveyor belt 550 can move the substrate left/right and forward/backward in the process chamber(s).

### Ion Implant

The conveyor belt 104 can also be used with an ion implant chamber. The substrate is grounded during ion implant processing. The substrate is also typically electrostaticly chucked for cooling. As in etch and CVD semiconductor methods, current ion implant methods are not cheap enough, fast enough nor able to deal with thin wafers. The belt is made of a material that can electrostaticly chuck the substrate, ground the substrate and provide cooling to the substrate. In some embodiments, the belt is a ceramic fabric belt driven by rollers on both end. The belt rides on top of a DC electrode which is cooled or kept at room temperature. The electrode is connected to a high voltage DC power supply to electrostaticly chuck the substrate. In some embodiments, wires are stitched across the belt perpendicular to the direction of travel. In one embodiment, the wires are stitched at about 50 mm periods. It will be appreciated that the wires may be switched at periods that are less than or more than 50 mm. The wires contact a grounded bar on the edges of the substrate outside the DC electrode. These wires provide a ground contact to the substrate to chuck the substrate and to eliminate charge buildup on the substrate. In some embodiments, the implant belt is made of the same material as the CVD belt and/or etch belt; however, the belts may be made of different materials. It will be appreciated that belt material may be select based on belt that is best for the particular process.

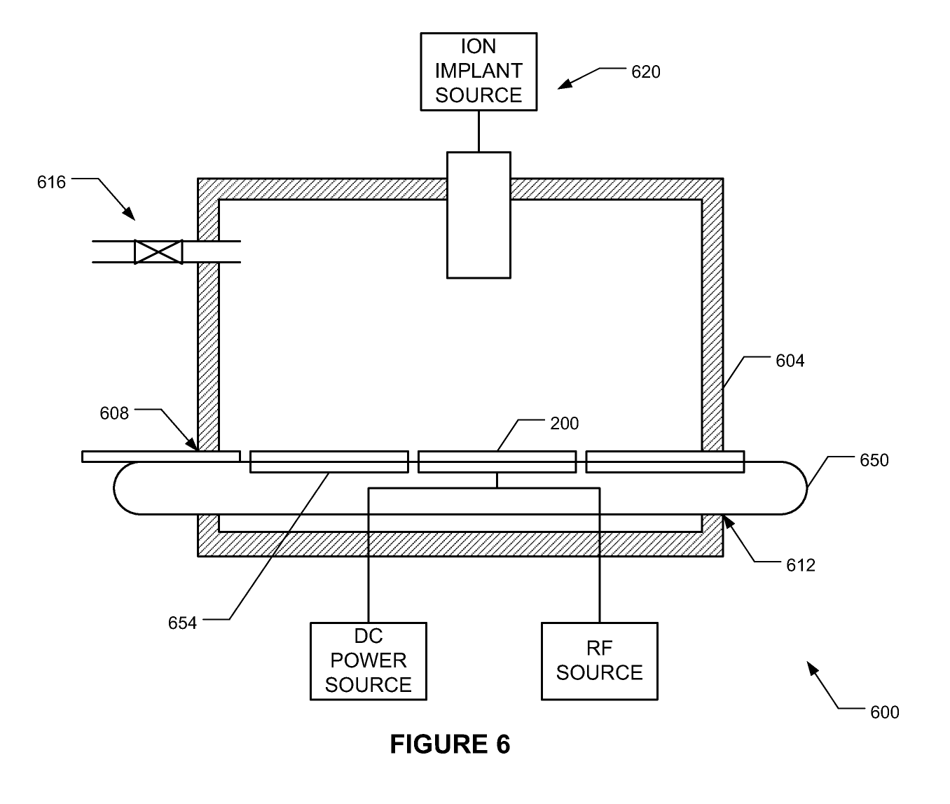

FIG. 6 illustrates an exemplary ion implant chamber 600 that includes a conveyor belt according to some embodiments of the invention. As shown in FIG. 6, the ion implant chamber 600 includes a vacuum chamber 604 with a substrate inlet 608, a substrate outlet 612, a vacuum system 616, and an ion implant source(s) 620. The ion implant chamber 600 also includes a conveyor belt 650 to transport substrates between the inlet 608 and the outlet 612. In some embodiments, the conveyor belt 650 is an aluminum oxide conveyor belt. The conveyor belt 650 can be operated in a start stop mode, a start/stop with left/right and forward backward/jog mode and/or a continuous motion mode. The chamber 600 also includes a cooled DC powered drag plate 654 to support the belt 650 and provide bias power, chuck and cool the substrate 200.

Embodiments of the invention are advantageous because it avoids the need for expensive robots, complicated lift pins and it reduces possible damage to the substrates. The jogging mode is advantageous because it can provide better uniformity for a homogeneous implant.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. A chemical vapor deposition (CVD) system comprising:
a CVD chamber comprising an inlet and an outlet; and
a conveyor belt to transport wafers from the inlet of the chamber to the outlet of the chamber.

2. The system of claim 1, wherein the conveyor belt comprises an aluminum oxide fabric belt.

3. The system of claim 1, wherein the conveyor belt comprises a roller at each end of the conveyor belt.

4. The system of claim 1, further comprising a grounded electrode, wherein the conveyor belt passes over the grounded electrode.

5. The system of claim 4, further comprising a grounded drag plate to support the conveyor belt and the grounded electrode.

6. The system of claim 1, wherein the conveyor belt operates in a continuous mode.

7. The system of claim 1, wherein the conveyor belt operates in a static mode.

8. The system of claim 1, wherein the conveyor belt operates in a start/stop with left/right and forward backward/jog mode.

9. The system of claim 1, wherein the chamber further comprises a vacuum system and a radio frequency (RF) powered shower head.

10. An etching system comprising:
an etch chamber comprising an inlet and an outlet; and
a conveyor belt to transport wafers from the inlet of the chamber to the outlet of the chamber.

11. The system of claim 10, wherein the conveyor belt comprises an aluminum oxide fabric belt.

12. The system of claim 10, wherein the conveyor belt comprises a roller at each end of the conveyor belt.

13. The system of claim 10, wherein the conveyor belt operates in a continuous mode.

14. The system of claim 10, wherein the conveyor belt operates in a static mode.

15. The system of claim 10, further comprising a direct current (DC) electrode coupled to the conveyor belt.

16. The system of claim 15, further comprising a cooled radio frequency (RF) biased drag plate coupled to the DC electrode, the drag plate to support the conveyor belt and provide bias power to the wafer, chuck the wafer and cool the wafer.

17. The system of claim 10, wherein the etch chamber further comprises a vacuum system and at least one radio frequency powered coil to generate the plasma for the chamber.

18. The system of claim 10, wherein the conveyor belt operates in a start/stop with left/right and forward/backward jog mode.

19. An ion implant system comprising:
an ion implant chamber comprising an inlet and an outlet; and
a conveyor belt to transport wafers from the inlet of the chamber to the outlet of the chamber.

20. The system of claim 19, wherein the conveyor belt comprises an aluminum oxide fabric belt.

21. The system of claim 19, wherein the conveyor belt comprises a roller at each end of the conveyor belt.

22. The system of claim 19, wherein the conveyor belt operates in a continuous mode.

23. The system of claim 19, wherein the conveyor belt operates in a static mode.

24. The system of claim 19, wherein the chamber further comprises a vacuum system and at least one ion implant source.

25. The system of claim 19, wherein the conveyor belt operates in a start/stop with left/right and forward backward/jog mode.
